(19) United States
(12) Patent Application Publication
(10) Pub. No.: US 2011/0117740 A1
(43) Pub. Date: May 19, 2011

(54) METHOD FOR POLISHING HETEROSTRUCTURES

(75) Inventors: Muriel Martinez, Saint Egreve (FR); Corinue Seguin, Meylan (FR); Morgane Logiou, St. Martin d'Heres (FR)

(73) Assignee: S.O.I. TEC Silicon on Insulator Technologies

(21) Appl. No.: 12/524,246

(22) PCT Filed: Jan. 23, 2008
(86) PCT No.: PCT/IB08/00156

§ 371 Date: Jul. 23, 2009

(30) Foreign Application Priority Data
Feb. 15, 2007 (FR) 0753284

(51) Int. Cl. H01L 21/304; H01L 29/34; H01L 21/306

(52) U.S. Cl. 438/693; 257/183; 257/E29.108; 257/E21.23

(57) ABSTRACT

A polishing method for a heterostructure of at least one relaxed superficial heteroepitaxial layer on a substrate made of a different material. The method includes a first chemical mechanical polishing step of the surface of the heteroepitaxial layer performed with a polishing cloth having a first compressibility ratio and with a polishing solution having a first silica particle concentration. The first chemical mechanical polishing step is followed by a second chemical mechanical polishing step of the surface of the heteroepitaxial layer, with the second step being performed with a polishing cloth having a second compressibility ratio, higher than the first compressibility ratio, and with a polishing solution having a second silica particle concentration, lower than the first concentration. By this method, improved surface roughness is achieved.

### BACKGROUND AND PRIOR ART

The present invention relates to the field of heterogeneous structures associating a buffer layer enabling a given strained material to be achieved on another different material. An example of such a heterostructure is the Si₍₁₋ₓ₎Ge₍ₓ₎ structure (x being able to vary from 20% to 100% according to the required degree of strain) comprising a relaxed Si₍₁₋ₓ₎Ge₍ₓ₎ buffer layer produced by epitaxy on a silicon substrate. When the Si₍₁₋ₓ₎Ge₍ₓ₎ layer is produced by epitaxy, the crystalline lattice mismatch between the silicon substrate and the subsequent SiGe layers results in the appearance of a strain lattice called “cross-hatch” at the surface of the SiGe buffer layer. This cross-hatch increases the surface roughness of the relaxed SiGe buffer layer. The surface of the relaxed SiGe buffer layer is then polished to eliminate the cross-hatch and to reduce the surface roughness. For this purpose, the surface of the relaxed SiGe buffer layer is planarized by chemical mechanical polishing (CMP), a well known polishing technique which implements a cloth associated with a polishing solution containing both an agent (e.g. NH₄OH) able to chemically etch the surface of the layer and abrasive particles (e.g. silica particles) able to mechanically etch said surface.

Solutions for eliminating cross-hatch and reducing the surface roughness on heterogeneous SiGe structures by CMP have been proposed.

The documents “Planarization of SiGe virtual substrate by CMP and its application to strained Si modulation-doped structures”, by K. Sawano et al, Journal of Crystal Growth, V251, p. 693-696 (2003) and “Surface smoothing of SiGe strain-relaxed buffer layers by chemical mechanical polishing” by K. Sawano et al, Material science and engineering B89 p. 406-409 (2002), describe a solution in which the SiGe structure is polished between two epitaxy steps so as to reduce the surface roughness to values of less than 1 nm RMS (about 0.4 nm for 10*10 μm² scan areas). However, the polishing rates obtained with this solution are relatively slow, a maximum removal rate of only 1.3 nm/sec being able to be achieved by adjusting the polishing pressure parameters.

The documents U.S. Pat. No. 6,988,936 and JP 11 197583 describe methods for finishing or recycling by chemical mechanical polishing of a silicon layer of a SOI (silicon on insulator) structure obtained by means of the SmartCut™ technology. However, these methods are not suitable for heterogeneous SiGe structures. The polishing rate obtained with these methods on silicon in fact decreases by a factor 5 when SiGe is involved (V_{Si}/V_{SiGe}=5).

The documents WO 2005/120775 and WO 2006/032298 divulge CMP methods of SiGe layers enabling not only a high removal rate to be achieved in a single polishing step by means of a “hard” or “intermediate” polishing/planarization cloth, but also a surface roughness of less than 0.2 nm RMS to be obtained for 10*10 pmt scan areas measured by atomic force microscope (AFM).

Although the polishing methods described in these two documents achieve a heterogeneous SiGe structure presenting a relatively low surface microroughness observed by AFM, they do not however guarantee a sufficient surface macroroughness level to meet the new quality demands required by ever-increasing miniaturization of the components to be produced for example on sSOI structures fabricated from a heterostructure (donor substrate) formed on a silicon support substrate on, which a relaxed SiGe layer is produced by means of a SiGe buffer layer, a strained silicon layer being formed on the relaxed SiGe layer.

The applicant has in fact observed that the surface macroroughness level determined by measuring the surface haze (low spatial frequency signal originating from the light diffused by the surface defects when the wafer or heterostructure is illuminated for example in SP1 measuring equipment) is a parameter that is just as important as the surface macroroughness level to qualify the surface state of a structure. As the surface roughness requirements on SiGe heterostructures after chemical mechanical polishing are increasingly stringent, characterization of the surface of these structures also has to take account of macroroughness measurement. Characterizations of SiGe heterostructures performed at low spatial frequency, i.e. by measuring the surface haze which is representative of the large-scale surface roughness (full wafer), have shown that a direct correlation exists between the surface macroroughness (haze level measured by SP1) and the final quality of the product. The technique used for measuring the haze level on wafers is in particular described in the document “Monitoring and Qualification Using Comprehensive Surface Haze Information” by F. Holsteyns et al, Semiconductor Manufacturing, 2003 IEEE International Symposium, p. 378-381.

The applicant thus highlighted that the haze level measured on the surface of the relaxed SiGe layer after CMP conditions the surface quality of the strained silicon layer formed on this layer, and consequently the efficiency of the resulting sSOI product (component integration capacity). In other words, the lower the post-CMP haze level, the higher the final product efficiency. Therefore, by reducing the post-CMP macroroughness (i.e. the surface roughness measured at low spatial frequency), the required surface quality requirements can be achieved to follow miniaturization of the components and circuits.

A need therefore exists to improve the surface roughness level obtained with the methods described in the documents WO 2005/120775 and WO 2006/032298.

### SUMMARY OF THE INVENTION

The object of the invention is to remedy the above-mentioned shortcomings and to propose a polishing or planarization solution whereby the roughness level present at the surface of heteroepitaxial layers and in particular the macroroughness (haze) level can be reduced even further.

This object is achieved with a polishing method of a heterostructure comprising at least one relaxed superficial heteroepitaxial layer on a substrate of a different material from that of said heteroepitaxial layer, a method wherein a first chemical mechanical polishing step of the surface of the heteroepitaxial layer, performed with a polishing cloth having a first compressibility ratio and with a polishing solution having a first silica particle concentration, is followed by a second chemical mechanical polishing step of the surface of the heteroepitaxial layer, said second step being performed with a polishing cloth having a second compressibility ratio, higher than the first compressibility ratio, and with a polishing solution having a second silica particle concentration lower than the first concentration.

When the first polishing step is performed, a “hard” polishing cloth is preferably used, for example a cloth having a compressibility ratio comprised between 2 and 4%, and in particular 2%. Although a cloth of such a hardness (2%) results in a greater microroughness (AFM 40*40 pmt) than that obtained with a cloth having an “intermediate” compressibility ratio, for example 6% as recommended in the document WO2005/120775, the combination of two steps of the method according to the invention enables both the strain lattice referred to as “cross-hatch”, the microroughness and the macroroughness referred to as “haze” to be eliminated more efficiently.

More precisely, the defects constituting cross-hatch are aligned with the crystalline lattice and are therefore particularly stable and difficult to planarize, whereas randomly arranged components of the microroughness are easier to eliminate. When the first polishing step is performed with a very hard cloth, the cross-hatch really does disappear, although the microroughness remains globally high, in particular with regard to its randomly arranged components which correspond for example to hardened zones due to polishing. Randomly arranged surface wave forms can in fact be observed, whereas the cross-hatch clearly presents a correlation with the crystalline axes. The random microroughness is then eliminated in the second polishing step which preferably comprises the use of an intermediate polishing cloth having for example a compressibility ratio of between 5% and 9%, and in particular of 6%.

Moreover, as the cross-hatch is eliminated in the first polishing step, the second polishing step enables the global microroughness to be reduced to a lower level than in the case of a method aiming to minimize the microroughness directly in a single step, which does not enable the cross-hatch to be completely eliminated.

According to one feature of the invention, in a first polishing step, the silica particles of the polishing solution have a diameter comprised within a first range of values whereas, in the second polishing step, the silica particles of the polishing solution have a diameter comprised within a second range of values at least partly lower than the values of the first range of values. In the first polishing step, the silica particles of the polishing solution can have a diameter comprised between 70 nm et 100 nm whereas, in the second polishing step, the silica particles of the polishing solution can have a diameter comprised between 60 nm and 80 nm.

According to another feature of the invention, in the first polishing step, the polishing cloth has a first compressibility ratio between 2% and 4% whereas, in the second polishing step, the polishing cloth has a second compressibility ratio comprised between 5% and 9%.

According to yet another feature of the invention, in the first polishing step, the polishing solution has a first silica particle concentration comprised between 28% and 30% whereas, in the second polishing step, the polishing solution has a second silica particle concentration comprised between 8% and 11%.

The above-mentioned parameters (compressibilities, concentrations and diameters of the silica particles) apply particularly when the heteroepitaxial layer is a silicon-germanium layer. However, the polishing method of the invention can be applied to other materials, for example to gallium arsenide GaAs or gallium nitride GaN.

Cross-hatch is thus eliminated in the first polishing step according to the invention with a relatively hard cloth compared with cloths which are suitable for polishing a predetermined material, in spite of a mediocre microroughness result compared with that obtained with an intermediate cloth. The microroughness and macroroughness are then eliminated with an intermediate cloth in the second polishing step according to the invention.

In this way, whatever the material, the method according to the invention enables the three above-mentioned forms of roughness to be reduced, i.e. cross-hatch, random microroughness and haze.

According to one feature of the invention, the heteroepitaxial layer is a silicon-germanium layer.

After the second chemical mechanical polishing step, the silicon-germanium heteroepitaxial layer presents a surface microroughness of less than 0.1 nm RMS for a roughness measurement made with an atomic force microscope on 2*2 μm² and 10*10 μm² scan areas.

In addition, after the second chemical mechanical polishing step the silicon-germanium heteroepitaxial layer presents a surface macro-roughness corresponding to a surface haze level of less than 0.5 ppm.

It should be noted that polishing according to the second step of the method of the invention is usually not used for treating silicon-germanium but only silicon, as it presents a very low polishing removal rate of about 0.2 nm/sec.

The polishing method of the invention described above can advantageously be used for fabrication of a sSOI structure according to the well known Smart Cut™ technology, this fabrication comprising formation of a strained silicon layer on a silicon-germanium heteroepitaxial layer belonging to a donor substrate, implantation of at least one atomic species in the donor substrate designed to form a weakened layer bonding the surface of the strained silicon layer with a surface of a receiver substrate, and detaching the layer in contact with the receiver substrate by cleavage at the level of the weakened layer formed in the donor substrate. In this case, before the strained silicon layer is formed, the silicon-germanium heteroepitaxial layer is polished according to the polishing method described above, which enables sSOI wafers of very good quality to be obtained thereby enabling the number of downgraded wafers to be reduced.

According to one feature of the invention, the receiver substrate comprises a thermal oxide layer at the level of its surface designed to be bonded with the strained silicon layer. The oxide layer is usually achieved on the donor substrate, before bonding, by means of an oxidation step of TEOS type which is complex to perform. Simple thermal oxidation does in fact present the drawback of reducing the thickness of the strained silicon layer too much, which layer thickness is already limited by the critical relaxation thickness. Inversely, the oxide layer can be achieved on the receiver substrate, before bonding, by means of a thermal oxidation step of the bulk silicon receiver substrate. However this requires a very good surface state of the strained silicon and of the silicon-germanium heteroepitaxial layer. By means of the method of the invention, a surface quality of the silicon-germanium heteroepitaxial layer is achieved, in particular as far as the cross-hatch and haze phenomena are concerned, enabling bonding of the strained silicon to be performed directly on a receiver substrate comprising the thermal oxide layer.

The present invention also relates to a heterostructure comprising at least one relaxed silicon-germanium superficial layer on a silicon substrate, the heteroepitaxial layer presenting a surface microroughness of less than 0.1 nm RMS for a roughness measurement made with an atomic force microscope on 2*2 μm² and 10*10 μm² scan areas.

The heteroepitaxial layer further presents a surface microroughness corresponding to a surface haze level of less than 0.5 ppm.

The invention also relates to a donor substrate designed to be used as crystalline growth seed for formation by epitaxy of at least one strained silicon layer comprising a heterostructure as described above.

### BRIEF DESCRIPTION OF THE FIGURES

FIG. 1 is a schematic representation of a polishing tool that can be used for implementing the polishing method according to an embodiment of the invention,

FIG. 2 is a schematic cross-sectional view of a heterostructure comprising a silicon-germanium layer formed by heteroepitaxy on a silicon substrate;

FIG. 3 is a box-plot diagram showing haze levels obtained after polishing performed in a single step and polishing performed in two steps according to the invention,

FIG. 4 is a histogram showing microroughness levels obtained after polishing performed in a single step and polishing performed in two steps according to the invention,

FIG. 5 is a histogram showing microroughness levels obtained after polishing performed in two steps according to the invention,

FIG. 6 is a box-plot diagram showing the final defectiveness rate obtained on sSOI wafers depending on whether the SiGe layer of the donor substrate has been subjected to polishing performed in a single step or polishing performed in two steps according to the invention,

FIG. 7 is a histogram showing the quality level and the status of sSOI wafers obtained after polishing performed in a single step and polishing performed in two steps according to the invention.

### DETAILED DESCRIPTION OF EMBODIMENTS OF THE INVENTION

The polishing method of the present invention comprises two chemical mechanical polishing steps, called CMP, that are performed consecutively but under different operating conditions. In particular, the first polishing step is performed with a relatively “hard” polishing cloth, i.e. having a low compressibility ratio, and with a polishing solution having a “high” concentration of silica particles having a diameter comprised in a range of “high” values.

What is meant by a low compressibility ratio is a low ratio compared with cloths that are suitable for polishing a predetermined material. In all events, the first compressibility ratio is low compared with the second compressibility ratio, which is referred to as “intermediate”. For a silicon-germanium heteroepitaxial layer for example, a cloth with a compressibility comprised between 2% and 4% is considered to be hard, whereas a compressibility of about 6% is defined as intermediate.

What is meant by a high concentration of silica particles is a high concentration compared with polishing solutions suitable for polishing a predetermined material. In all events, the first concentration is high compared with the second concentration, which is thus referred to as “low”. For a silicon-germanium heteroepitaxial layer for example, a concentration of less than 12% is considered to be low, whereas a concentration of more than 20% is defined as high.

What is meant by a range of high values are values that are high (for example the majority or a mean of the values are high) compared with polishing solutions suitable for polishing a predetermined material. In all events, the values of the first range are essentially high compared with the values of the second range, which are thus referred to as “low”, although partial overlapping of the ranges is not excluded. The particles of a particular solution are in fact never all of the same diameter and it is inevitable for the diameter distributions of different solutions to overlap. Thus, for a silicon-germanium heteroepitaxial layer for example, a range of values between 60 and 80 nm is considered as being a range of low values, whereas a range of values between 70 and 100 nm is considered as being a range of high values.

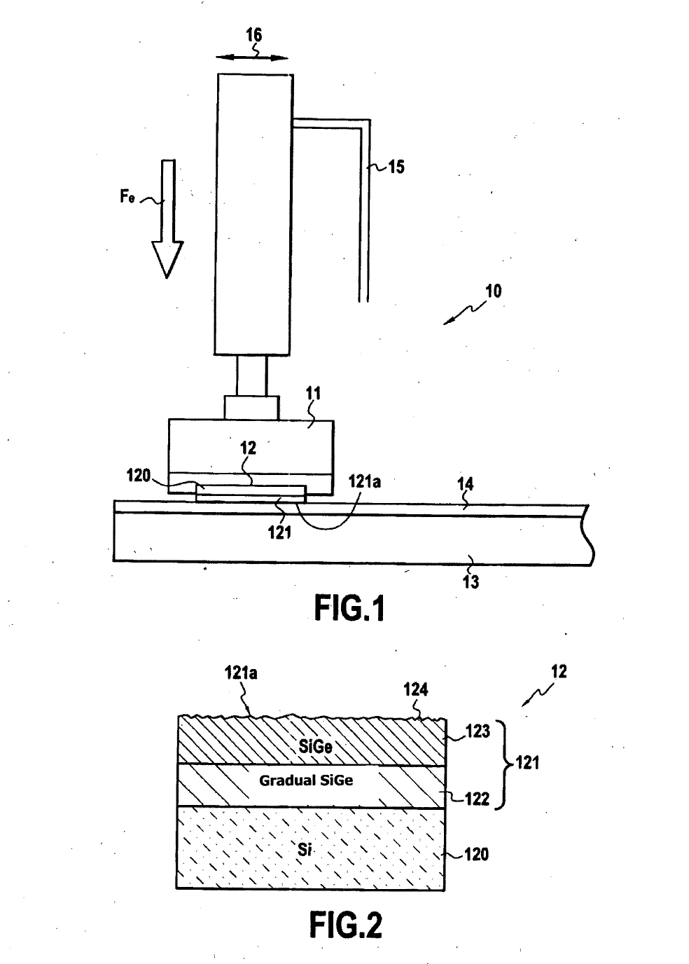

FIG. 1 illustrates a polishing tool 10 which can be used to implement the polishing method according to an embodiment of the invention. Tool 10 comprises on the one hand a polishing head 11 in which a heterostructure 12 presenting a surface roughness to be polished is inserted, and on the other hand a plate 13 covered by a polishing cloth 14. Polishing head 11 and plate 13 are respectively driven in rotation to polish surface 121a of heterostructure 12 in contact with polishing cloth 14. A polishing pressure Fe and a translation movement represented by an arrow 16 are in addition applied to head 11 when polishing is performed. When polishing is performed, an abrasive polishing solution formed by at least one colloidal solution such as a NH₄OH solution containing silica particles is in addition injected into polishing head 11 via a tube 15 and dispensed by the latter on polishing cloth 14. Polishing of surface 121a of heterostructure 12 is consequently performed with polishing cloth 14 impregnated with polishing solution.

Heterostructure 12 is formed by at least one heteroepitaxial layer 121 formed on a substrate 120 made from a different material, the heteroepitaxial layer being relaxed and presenting a strain lattice or cross-hatch requiring polishing at its surface. As illustrated in FIG. 2, heterogeneous structure 12 can be formed by a relaxed buffer layer of Si₍₁₋ₓ₎Ge₍ₓ₎ 121 comprising a gradual layer of Si₍₁₋ₓ₎Ge₍ₓ₎122 (x varying for example from 0 to 0.2 in the thickness of the layer) and a uniform Si₍₁₋ₓ₎Ge₍ₓ₎ layer 123 (for example x=0.2) formed by heteroepitaxy on a silicon substrate 120. The crystalline lattice mismatch between the silicon substrate and the SiGe layers formed thereon results, when the strains are relaxed, in formation of a cross-hatch relaxation roughness 124 at the surface of SiGe layer 123 corresponding to surface 121a of heterostructure 12. After removal of the cross-hatch according to the polishing method of the invention described further on, heterostructure 12 can be used to form a strained silicon layer sSi which can then be transferred onto a receiver substrate such as a silicon substrate, using for example the well known SmartCut™ technology. After the sSi layer has been transferred, the heterostructure can be reused for formation of a new sSi layer after the fractured surface of the SiGe layer of the heterostructure has been polished, again according to the method of the invention.

In the first polishing step, the surface of heterostructure 12 undergoes chemical mechanical polishing performed with a polishing cloth that is called “hard”, i.e. a cloth presenting a compressibility ratio comprised between 2% and 4%, preferably 2%.

The first chemical mechanical polishing step is also performed with a polishing solution that is called “aggressive”, i.e. a colloidal solution, for example a NH₄OH solution containing at least 20% of silica particles with a diameter comprised between 70 and 100 nm, and preferably between 28% and 30% of silica particles.

The removal rate of the first polishing step is preferably 3 nm/sec and the duration of the first step is about 2 minutes.

This first chemical mechanical polishing step eliminates the cross-hatch and reduces the surface microroughness to about 0.2 nm RMS, a roughness value measured by atomic force microscope (AFM) for scan areas of 10*10 μm².

However, after this first polishing step, heterostructure 12 presents at its surface 121a a macroroughness level of about 20 ppm corresponding to the measured surface haze level (low spatial frequency signal from the light diffused by the surface defects when the wafer or heterostructure is illuminated for example in a SP1 measuring apparatus).

According to the invention, a second chemical mechanical polishing step is performed to reduce the macroroughness level present at the surface of the heterostructure.

This second polishing step of surface 121a of heterostructure 12 is performed with a polishing cloth called “intermediate”, i.e. a cloth presenting a compressibility ratio comprised between 5% and 9%, preferably 6%. In this second step, the polishing cloth preferably corresponds to the cloth used for silicon finishing polishing in fabrication of SOI (Silicon On Insulator) structures. A known example of such a polishing cloth is the SPM 3100 cloth supplied by Rohm & Haas.

The second chemical mechanical polishing step is performed with a “softer” polishing solution than the one used in the first step, i.e. a colloidal solution, for example a NH₄OH solution, containing a percentage of silica particles of less than about 12%, the silica particles having a diameter comprised between 60 and 80 nm. The percentage of silica particles is preferably between 8% and 11%.

The removal rate of the second polishing step is preferably 0.2 nm/sec and the duration of the second step is about 3 minutes.

This second chemical mechanical polishing step enables the surface microroughness to be reduced to a value of less than 0.1 nm RMS, a roughness value measured with an atomic force microscope (AFM) for scan areas of 2*2 μm². This second step above all enables a surface macroroughness level of about 0.5 ppm corresponding to the surface haze level measured with a SP1 measuring apparatus to be obtained at surface 121a of heterostructure 12. The haze level obtained after the two polishing steps described above is improved by a factor 40 compared with that obtained with the first polishing step only.

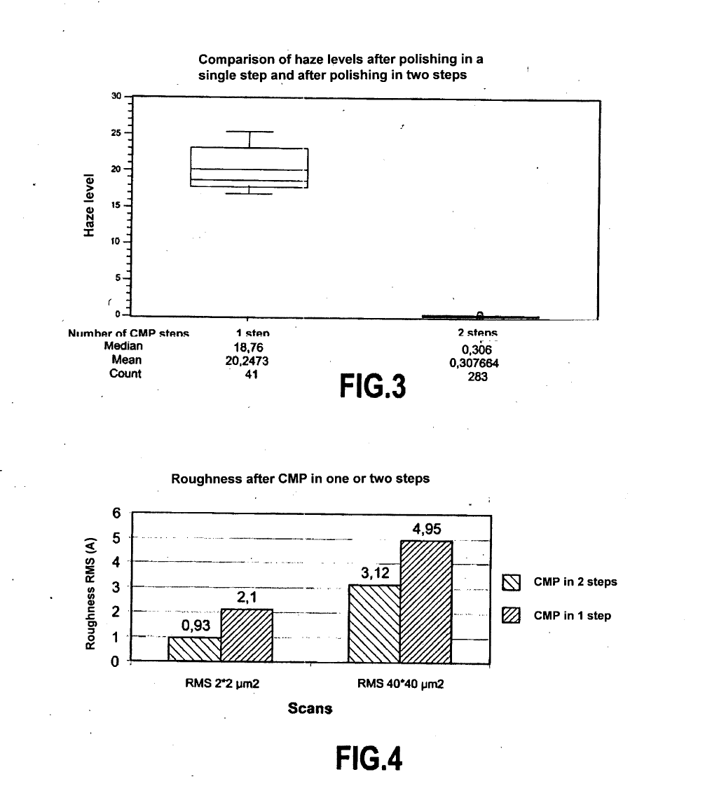

FIG. 3 represents the haze level obtained after polishing of a SiGe layer formed on a silicon substrate as in previously described heterostructure 12, chemical mechanical polishing being performed respectively either in a single step corresponding to the previously described first polishing step, or in two steps corresponding to the previously described first and second steps. The values indicated in FIG. 3 were measured with a SP1 measuring apparatus from KLA-Tencor with the detection threshold adjusted to 0.13 microns, i.e. the minimum size of detectable particles.

This figure clearly shows the gain obtained on the haze level when chemical mechanical polishing is performed in two steps according to the invention. Thus, the haze level after CMP drops from a mean of 19 ppm to a mean of 0.31 ppm due to the second polishing step.

FIG. 4 shows the surface microroughness RMS values obtained on SiGe heteroepitaxial layers after CMP performed in a single step and in two steps according to the invention. The surface microroughness values presented were measured with an atomic force microscope (AFM) for scan areas of 2*2 μm² and 40*40 μm².

The values indicated in FIG. 4 show that the surface microroughness obtained with CMP performed in two steps according to the invention is reduced by a factor 2 for 2*2 μm² scan areas and by a factor 1.5 for 40*40 μm² scan areas. The microroughness after CMP in two steps is therefore less than 0.1 nm RMS for 2*2 μm² scan areas, which ensures a very good surface state for performing for example resumption of strained silicon epitaxy or molecular bonding.

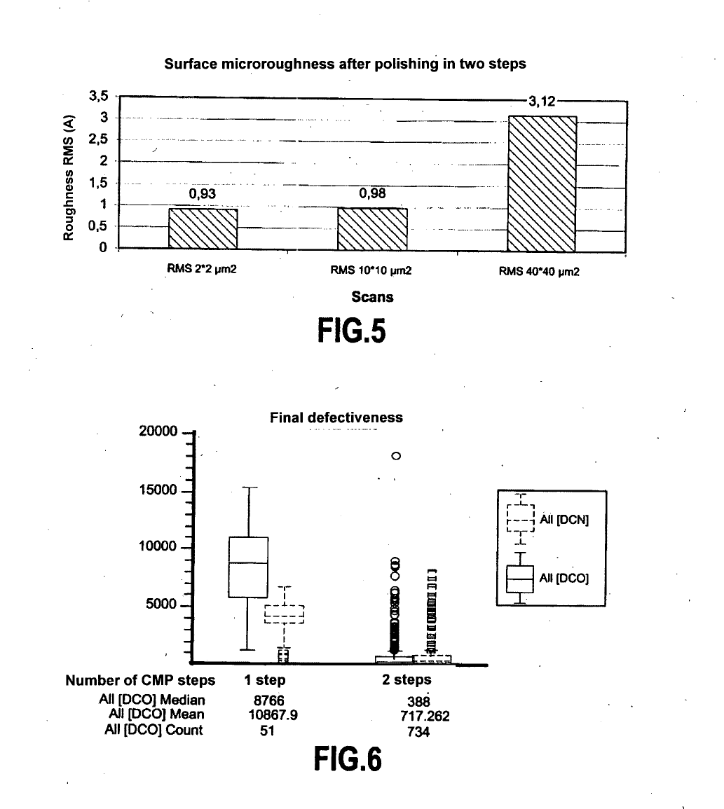

FIG. 5 indicates, in addition to the surface microroughness values already presented in FIG. 4 for 2*2 μm² and 40*40 μm² scan areas, the surface microroughness value measured with an atomic force microscope (AFM) on the same SiGe layer for 10*10 μm² scan areas. This figure shows that the surface microroughness obtained for 2*2 μm² scan areas is similar with a larger scan area of 10*10 μm².

The SiGe layer or layers the results of which are presented in FIGS. 3 to 5 were polished with a Mirra polishing apparatus from Applied Materials with the following rotation speeds of the polishing head Vt and of the plate Vp:
first polishing step: Vt comprised between 75 and 95 rpm, preferably 87 rpm, with a pressure applied to the polishing head comprised between 5 and 9 psi, preferably 7 psi; Vp comprised between 85 and 100 rpm, preferably 93 rpm;
second polishing step: Vt comprised between 30 and 45 rpm, preferably 36 rpm, with a pressure applied to the polishing head comprised between 3 and 6 psi, preferably 5 psi; Vp comprised between 25 and 40 rpm, preferably 30 rpm;

FIG. 6 represents the defectiveness level observed on sSOI (strained silicon on insulator) wafers made from heterostructures whose SiGe layer, which acted as growth layer for the strained silicon layer, underwent CMP performed either in a single step corresponding to the first polishing step described above or in two steps corresponding to the first and second polishing steps described above.

The values indicated in FIG. 6 were measured with a SP1 measuring apparatus from KLA-Tencor with the detection threshold adjusted to 0.4-0.5 microns, i.e. the minimum size of detectable particles.

FIG. 6 enables the total defectiveness (represented by the number of defects indicated on the y-axis) measured obliquely (corresponding to ALL [DCO] (All Defect Composite Oblique) in FIG. 6) and the total defectiveness measured perpendicularly (corresponding to ALL [DCN] (All Defect Composite Normal) in FIG. 6) to be compared depending on whether CMP was performed in a single step or in two steps. It can be observed that polishing performed in two steps under the conditions described above enables the defectiveness on the final sSOI product to be improved by a factor 20 compared with polishing performed in a single step (comparison of “Median All [DCO]”).

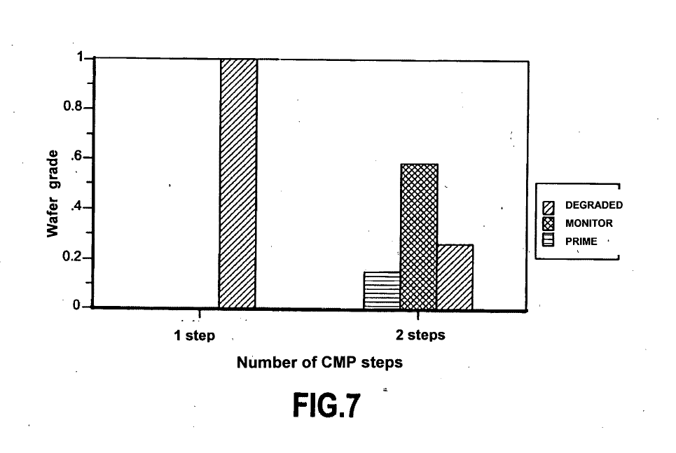

FIG. 7 represents the status attributed to sSOI wafers depending on whether the SiGe layer of the heterostructures from which the latter were produced underwent CMP either in a single step corresponding to the first polishing step described above or in two steps corresponding to the first and second polishing steps described above. In FIG. 7, the “Prime” status corresponds to the best grade for the wafers, according to customer specifications, the “Monitor” status corresponds to a less good quality grade (the wafers are potentially deliverable with less constraining final specifications than for the “Prime” grade), and the “Downgraded” status corresponds to scrapping of a wafer which is too defective.

In FIG. 7, the impact of the second polishing step on the final wafer yield can clearly be seen. With polishing in a single step, the final yield is in fact 100% of downgraded wafers, whereas with polishing in two steps, it is:
18% “Prime”,
52% “Monitor”, and
30% “Downgraded”, i.e. 3 times less than for polishing in a single step.

The polishing method described above for polishing a SiGe heteroepitaxial layer can also be implemented for polishing heteroepitaxial layers of gallium arsenide GaAs and gallium nitride GaN. The parameters (cloth compressibility in the 1^{st} and 2^{nd} steps, silica particle concentration/particle diameter in the 1^{st} and 2^{nd} steps, etc.) indicated in relation with polishing a SiGe layer are also applicable for polishing a GaAs or GaN heteroepitaxial layer.

Consequently, by implementing two polishing steps under the previously defined conditions, the polishing method of the present invention enables cross-hatch, macroroughness (haze measurement) and surface microroughness (measured with an atomic force microscope (AFM)) to be considerably reduced. This improvement on the surface state of the wafers in particular ensures good molecular bonding and/or strained silicon epitaxy resumption. It further enables a better quality of wafers to be obtained at the end of the method for fabricating sSoi wafers since the number of downgraded wafers at the outcome is reduced by a factor 3, which considerably increases the number of very good quality wafers.

1.-17. (canceled)

18. A method for polishing a heterostructure comprising at least one relaxed superficial heteroepitaxial layer on a substrate made from a material that is different from that of the heteroepitaxial layer, which method comprises:
performing a first chemical mechanical polishing on the surface of the heteroepitaxial layer for a first period of time with a polishing cloth having a first compressibility ratio and with a polishing solution having a first silica particle concentration,
subsequently performing a second chemical mechanical polishing step on the surface of the heteroepitaxial layer for a second period of time with a polishing cloth having a second compressibility ratio, higher than the first compressibility ratio, and with a polishing solution having a second silica particle concentration lower than the first concentration, to reduce surface roughness compared to performing a single chemical mechanical polishing step using a single polishing cloth and a single polishing solution for a time period that is the same as that of the combined first and second periods of time of the first and second chemical mechanical polishing steps.

19. The method of claim 18, wherein the first polishing step is performed with a polishing solution that contains silica particles having diameters within a first range of values and the second polishing step is performed with a polishing solution that contains silica particles having diameters within a second range of values, wherein the second range of values is at least partly lower than the first range of values.

20. The method of claim 18, wherein the first polishing step is performed with a polishing cloth having a first compressibility ratio that is between 2% and 4%.

21. The method of claim 18, wherein the second polishing step is performed with a polishing cloth having a second compressibility ratio that is between 5% and 9%.

22. The method of claim 18, wherein the first polishing step is performed with a polishing solution having a first silica particle concentration that is between 28% and 30%.

23. The method of claim 18, wherein the second polishing step is performed with a polishing solution having a second silica particle concentration that is between 8% and 11%.

24. The method of claim 19, wherein the first polishing step is performed with the silica particles of the polishing solution having a diameter that is between 70 nm and 100 nm.

25. The method of claim 19, wherein the second polishing step is performed with the silica particles of the polishing solution having a diameter that is 60 nm and 80 nm.

26. The method of claim 18, wherein the heteroepitaxial layer is a silicon-germanium layer, and the substrate includes a silicon support.

27. The method of claim 26, wherein after the second chemical mechanical polishing step is performed, the surface roughness of the silicon-germanium heteroepitaxial layer is reduced to less than 0.1 nm RMS for a roughness measurement made with an atomic force microscope on 2*2 μm² and 10*10 μm² scan areas.

28. The method of claim 26, wherein after the second chemical mechanical polishing step is performed, the silicon-germanium heteroepitaxial layer presents a surface macroroughness corresponding to a surface haze level of less than 0.5 ppm.

29. The method of claim 18, wherein the first and second chemical mechanical polishing steps are performed in a polishing tool comprising a polishing head in which the heterostructure is arranged and a plate covered by a polishing cloth in contact with the surface of the heteroepitaxial layer to be polished, with the polishing solution being dispensed from the polishing head.

30. A fabrication method of a sSOI structure which comprises:
polishing a silicon-germanium heteroepitaxial layer belonging to a donor substrate according to the method of claim 18;
forming a strained silicon layer on the polished silicon-germanium heteroepitaxial layer;
implanting at least one atomic species in the donor substrate designed to form a weakened layer;
bonding a surface of the donor substrate with a surface of a receiver substrate; and
detaching a layer of the donor substrate in contact with the receiver substrate by cleavage at the weakened layer to form the sSOI structure.

31. The method of claim 30, wherein the receiver substrate comprises a thermal oxide layer on its bonding surface.

32. A heterostructure comprising at least one relaxed silicon-germanium superficial heteroepitaxial layer on a silicon substrate; wherein the heteroepitaxial layer has a surface that is polished to present a surface microroughness of less than 0.1 nm RMS for a roughness measurement made with an atomic force microscope on 2*2 μm² and 10*10 μm² scan areas.

33. The heterostructure of claim 32, wherein the polished heteroepitaxial layer surface also presents a surface macroroughness corresponding to a surface haze level of less than 0.5 ppm.

34. A donor substrate designed to be used as a crystalline growth seed for formation by epitaxy of at least one strained silicon layer thereon, which comprises a heterostructure according to claim 32.

35. A donor substrate designed to be used as a crystalline growth seed for formation by epitaxy of at least one strained silicon layer thereon, which comprises a heterostructure according to claim 33.
